(19) United States
(12) Patent Application Publication
(10) Pub. No.: US 2025/0308866 A1
(43) Pub. Date: Oct. 2, 2025

(54) FLUORINATION CLEANING METHOD AND APPARATUS FOR FORMING YTTRIUM OXYFLUORIDE ON YTTRIA-COATED PART FOR SEMICONDUCTOR DRY ETCHING SYSTEM

(71) Applicant: WONIK QNC Corporation, Gumi-si (KR)

(72) Inventors: Eun Young CHOI, Hwaseong-si (KR); Joo Hee JANG, Hwaseong-si (KR); Dong Ho SHIN, Seoul (KR); Min Seob JUNG, Seoul (KR)

(73) Assignee: WONIK QNC Corporation, Gumi-si (KR)

(21) Appl. No.: 19/073,875

(22) Filed: Mar. 7, 2025

(30) Foreign Application Priority Data
Mar. 27, 2024 (KR) 10-2024-0041487

(51) Int. Cl. H01J 37/32; C23C 16/02; C23C 16/30

(52) U.S. Cl. CPC H01J 37/32862; C23C 16/0218; C23C 16/30; H01J 37/32357; H01J 37/32449; H01J 2237/332

(57) ABSTRACT

Disclosed are a fluorination cleaning method and a fluorination cleaning apparatus for forming yttrium oxyfluoride on an yttria-coated part for a semiconductor dry etching system. The fluorination cleaning method includes: a part placement step of placing the yttria-coated part in a process chamber; a process gas introduction step of introducing a discharge gas, a non-fluorine reactive gas, and a reactive gas, which are process gases for fluorination cleaning, into the process chamber; a plasma heat treatment step of applying heat and plasma to the process chamber; and a cleaning process control step of controlling process parameters of the process gas introduction step and the plasma heat treatment step so that a fluoride layer is formed on an yttria coating layer of the yttria-coated part.

### BACKGROUND

### 1. Technical Field

The present disclosure relates to a fluorination cleaning method and a fluorination cleaning apparatus for forming yttrium oxyfluoride on an yttria-coated part for a semiconductor dry etching system. More specifically, the present disclosure relates to a fluorination cleaning method and a fluorination cleaning apparatus for forming yttrium oxyfluoride on an yttria-coated part for a semiconductor dry etching system, which, by forming an yttrium oxyfluoride (YOF) layer on the yttria (Y₂O₃) coating layer of the yttria-coated part by performing plasma heat treatment using process gases, including CF₄ reactive gas, under specific treatment conditions, may shorten the time of an aging process for ensuring a normal etching rate in a seasoning process for the dry etching system.

### 2. Related Art

Among semiconductor manufacturing systems, a semiconductor dry etching system should be shut down for regular system inspection or parts replacement (maintenance), and then subjected to a back-up process to ensure normal operation of the semiconductor manufacturing system before restart of the system.

The back-up process for the semiconductor dry etching system is performed through several steps: an out-gassing step of removing water and the like from the system; a step of reducing contaminant particles in the system; an aging step of fluorinating the inside of the system; and a step of verifying sample quality (In Fab. Data) step using mass-produced wafers.

Thereamong, an aging process is performed to form a fluoride atmosphere capable of ensuring a normal etching rate in the semiconductor dry etching system. In this aging process, a certain level of etching gas is allowed to react with the surface of plasma-resistant coatings (Al₂O₃, Y₂O₃, YAG, etc.) provided in the system to form a fluoride layer having a composition containing F element on the surface to a thickness of several nm to several hundred nm.

If a fluorine atmosphere is not sufficiently formed in the semiconductor dry etching system, a problem may arise in that the time for repeating the aging process becomes longer, leading to a significant reduction in the normal etching process time, which may cause a decrease in the productivity of the semiconductor manufacturing system and an increase in the manufacturing cost.

As an example of a conventional method for forming a fluoride layer, a method is known in which a part to be fluorinated is placed in a vacuum chamber, and then a low-pressure vacuum plasma is generated using a fluorine-containing gas such as CF₄, SF₆, or NF₃, so that the surface is fluorinated by fluorine-containing radicals (“Fabrication, characterization, and fluorine-plasma exposure behavior of dense yttrium oxyfluoride ceramic”, T Tsunoura et al., Japanese Journal of Applied Physics 56, 06HC₀₂ (2017), “Fluorination mechanisms of Al₂O₃ and Y₂O₃ surfaces irradiated by high-density CF₄/O₂ and SF₆/O₂ plasmas”, K Miwa et al, J Vac Sci Technol A 27(4), July/August 2009).

However, this method has disadvantages in that it requires the construction of a vacuum chamber and corresponding vacuum devices, which is disadvantageous for mass production and results in low economic feasibility, and in that, since it uses a low-pressure plasma process, the density of fluorine-containing radicals is low, and thus the fluorination rate is low, leading to low productivity.

As another example, a method is known in which a part to be fluorinated is immersed in a solution of HF, SF₄, CHF₃ or the like, and then the surface thereof is fluorinated by increasing the temperature to about 250° C. (“Preparation of Fluorinated-γ-Alumina”, E Kemnitz et al., “Efficient Preparations of Fluorine Compounds”, Edited by H W Roesky, 2013, 442).

However, this method has a disadvantage in terms of process safety because it uses a hazardous solution during the handling and treatment processes.

In addition, as other examples, U.S. Pat. No. 8,206,829 and/or US Patent Application Publication No. 2017/0114440 are known. These documents disclose a method of coating the surface of a part with a powder material such as AlF₃, YF₃, AlOF, or YOF by a method such as plasma spraying.

However, there is a disadvantage in that, since the raw material price of AlF₃ or YF₃, which is a coating raw material used for a ceramic protective coating such as alumina (Al₂O₃) or yttria (Y₂O₃), is very high and the supply of the raw material is not smooth as the raw material suppliers are limited, economic feasibility is low. In addition, when the fluoride coating is formed by the above method, a problem may arise in that that relatively more particles than Y₂O₃ can be generated due to physical impact caused by ion particles in the plasma, which lowers the reliability of the fluoride coating.

### PATENT DOCUMENTS

Korean Patent No. 10-1309716 (published on Sep. 17, 2013)
U.S. Pat. No. 8,206,829 (registered on Jun. 26, 2012) US Patent Application Publication No. 2017/0114440 (published on Apr. 27, 2017)

### SUMMARY

Therefore, the present disclosure has been made in order to solve the above-described problems occurring in the prior art, and an object of the present disclosure is to provide a fluorination cleaning method and a fluorination cleaning apparatus for forming yttrium oxyfluoride on an yttria-coated part for a semiconductor dry etching system, which, by forming an yttrium oxyfluoride (YOF) layer on the yttria (Y₂O₃) coating layer of the yttria-coated part by performing plasma heat treatment using process gases, including CF₄ reactive gas, under specific treatment conditions, may shorten the time of an aging process for ensuring a normal etching rate in a seasoning process for the dry etching system.

In accordance to one aspect of the present disclosure for achieving the objects and other features of the present disclosure, there is provided a fluorination cleaning method for forming yttrium oxyfluoride on an yttria (Y₂O₃)-coated part for a semiconductor dry etching system, including: a part placement step of placing the yttria-coated part in a process chamber; a process gas introduction step of introducing a discharge gas, a non-fluorine reactive gas, and a reactive gas, which are process gases for fluorination cleaning, into the process chamber; a plasma heat treatment step of applying heat and plasma to the process chamber; and a cleaning process control step of controlling process parameters of the process gas introduction step and the plasma heat treatment step so that a fluoride layer is formed on the yttria coating layer of the yttria-coated part.

In the present disclosure, the cleaning process control step may include controlling a combination of a plurality of process parameters among process parameters, including process gas introduction amounts, plasma generation power, treatment time, heat treatment temperature, treatment space pressure, the distance between plasma and the part, and the number of treatment cycles.

In the present disclosure, the cleaning process control step may include controlling the process parameters so that an yttrium oxyfluoride layer is formed on the yttria-coating layer of the yttria-coated part.

In the present disclosure, the cleaning process control step may include controlling plasma generation power, heat treatment temperature, treatment space pressure, process gas flow rates, and treatment time as the process parameters.

In the present disclosure, the cleaning process control step preferably includes controlling the plasma generation power (RF power) to 100 W to 1200 W, the heat treatment temperature to room temperature to 600° C., the treatment space pressure to 90 mTorr to 110 mTorr, the flow rate ratio between the non-fluorine reactive gas and the fluorine-containing reactive gas CF₄ to 0:100, and the treatment time to 15 to 180 minutes.

In the present disclosure, the cleaning process control step may include controlling LF plasma generation power, heat treatment temperature, treatment space pressure, process gas flow rates, and treatment time as the process parameters.

In the present disclosure, the cleaning process control step preferably include controlling the LF plasma generation power to 300 W to 1200 W, the heat treatment temperature to room temperature to 600° C., the treatment space pressure to 90 mTorr to 550 mTorr, the flow rate ratio between discharge gas (Ar), the non-fluorine reactive gas (O₂), and fluorine-containing reactive gas (CF₄) to 0:(10 to 90):(10 to 90) or 50:(10 to 50):(18 to 45), and the treatment time to 15 to 60 minutes.

In the present disclosure, the cleaning process control step includes controlling plasma generation power, the flow rate ratio between the non-fluorine reactive gas (O₂) and the fluorine-containing reactive gas (CF₄), and treatment time as the process parameters, and further includes controlling at least one of the distance between the plasma and the part, and the number of treatment cycles.

In the present disclosure, the cleaning process control step preferably includes controlling the LF plasma generation power to 1 kW to 7 kW, the flow rate ratio between the non-fluorine reactive gas (O₂) and the fluorine-containing reaction gas (CF₄) to 90:10 or 0:100, the treatment time to 15 to 60 minutes, and the distance between the plasma and the part to 30 to 50 mm.

In the present disclosure, the cleaning process control step may include controlling at least one of microwave power for remote plasma generation, bias plasma power, the flow rate ratio between the non-fluorine reactive gas (O₂) and the fluorine-containing reactive gas (CF₄), and the treatment time as the process parameters.

In the present disclosure, the cleaning process control step preferably includes controlling the microwave power for remote plasma generation to 1 kW to 2 kW, the bias plasma power to 500 W to 1000 W (2 MHz plasma), the flow rate ratio between the non-fluorine reactive gas (O₂) and the fluorine-containing reactive gas (CF₄) to 10:1, and the treatment time to 15 minutes.

The fluorination cleaning method and the fluorination cleaning apparatus for forming yttrium oxyfluoride on an yttria-coated part for a semiconductor dry etching system according to the present disclosure have the following effects.

First, the present disclosure has the effect of shortening the time of aging for ensuring a normal etching rate in a seasoning process for the semiconductor dry etching system, thereby improving productivity.

Second, the present disclosure has an excellent effect of equipment compatibility because the composition of YOF may be controlled.

Third, the present disclosure has the effect of increasing the coating life of a part coated with a plasma-resistant coating material, thereby increasing economic efficiency.

Fourth, the present disclosure has the effect of imparting high density and high strength to an yttria (Y₂O₃)-coated part for a semiconductor dry etching system, and maximally reducing the generation of contaminant particles to ensure a normal etching rate.

### BRIEF DESCRIPTION OF THE DRAWINGS

FIG. 1 is a flowchart showing a fluorination cleaning method for forming yttrium oxyfluoride on an yttria-coated part for a semiconductor dry etching system according to the present disclosure.

FIG. 2 schematically shows a plasma generation mode of a first embodiment, which is executed in a cleaning process control step included in a fluorination cleaning method for forming yttrium oxyfluoride on an yttria-coated part for a semiconductor dry etching system according to the present disclosure.

FIG. 3 schematically shows a plasma generation mode of a second embodiment, which is executed in a cleaning process control step included in a fluorination cleaning method for forming yttrium oxyfluoride on an yttria-coated part for a semiconductor dry etching system according to the present disclosure.

FIG. 4 schematically shows a plasma generation mode of a third embodiment, which is executed in a cleaning process control step included in a fluorination cleaning method for forming yttrium oxyfluoride on an yttria-coated part for a semiconductor dry etching system according to the present disclosure.

FIG. 5 schematically shows a plasma generation mode of a fourth embodiment, which is executed in a cleaning process control step included in a fluorination cleaning method for forming yttrium oxyfluoride on an yttria-coated part for a semiconductor dry etching system according to the present disclosure.

FIG. 6 shows the results of observing the coating layer of an yttria-coated part for a semiconductor dry etching system using an electron microscope after performing fluorination cleaning through a fluorination cleaning method for forming yttrium oxyfluoride on an yttria-coated part according to the present disclosure.

FIG. 7 is a block diagram schematically showing the configuration of a fluorination cleaning apparatus for forming yttrium oxyfluoride on an yttria-coated part for a semiconductor dry etching system according to the present disclosure.

FIG. 8 is a table showing the results of comparing the surface microstructure depending on power and the F content depending on power and depth.

FIG. 9 is a table showing the results of comparing the surface microstructure depending on the O₂ flow rate at a fixed power in RIE mode and the C and F contents depending on the O₂ flow rate and depth.

FIG. 10 is a table showing the results of comparing the surface/cross-section microstructure depending on the reaction temperature and the F content according to the reaction temperature and depth.

FIG. 11 is a table showing the results of performing XRD analysis depending on the reaction temperature.

FIG. 12 is a table showing the results of comparing the surface microstructure depending on power and the F content depending on power and depth.

FIG. 13 is a table showing the results of comparing the surface microstructure depending on the reaction time and the F content and C content depending on the reaction time and depth.

FIG. 14 is a table showing the results of comparing the surface microstructure depending on the chamber working pressure (treatment pressure) and the F content depending on the working pressure and depth.

FIG. 15 is a table showing the results of comparing the surface microstructure depending on the gas flow ratio between O₂ and CF₄, and the F content and C content depending in the gas flow ratio between O₂ and CF₄ and depth.

FIG. 16 is a table comparing the surface microstructure and the F content depending on the distance from the electrode, LF (low frequency) plasma power, and reaction time in floating mode.

FIG. 17 is a table showing the results of comparing the surface microstructure and the F content depending on power and the number of cycles.

FIG. 18 is a table showing the results of performing fluorination cleaning on Y₂O₃ using the process parameters of the fourth embodiment.

### DETAILED DESCRIPTION

Specific embodiments according to the present disclosure will be described below with reference to the accompanying drawings. However, this is not intended to limit the invention to any particular embodiment, and is to be understood to include all modifications, equivalents, and substitutions that fall within the idea and technical scope of the invention.

Throughout the specification, parts having like construction and operation are designated by the same reference signs. In addition, the accompanying drawings of the present disclosure are for the convenience of illustration only, and shapes and relative dimensions thereof may be exaggerated or omitted.

In describing embodiments in detail, redundant descriptions or descriptions of techniques that are obvious in the field are omitted. In addition, whenever any part is the to “include” other components in the following description, it is intended to include components in addition to those listed, unless the contrary is specifically indicated.

In addition, terms such as “part,” “section,” “module,” and the like used herein mean a unit that performs at least one function or operation, which may be implemented in hardware, software, or a combination of hardware and software. Also, when one part is the to be electrically connected to another part, this includes direct connections as well as connections with other configurations in between.

Terms containing ordinal numbers, such as first, second, and the like, may be used to describe various components, but the components are not limited by such terms. These terms are used only to distinguish one component from another. For example, a second component may be named as a first component, and similarly, a first component may be named as a second component, without departing from the scope of the present disclosure.

Hereinafter, the fluorination cleaning method and the fluorination cleaning apparatus for forming yttrium oxyfluoride on an yttria-coated part for a semiconductor dry etching system according to preferred embodiments of the present disclosure will be described in detail with reference to the accompanying drawings.

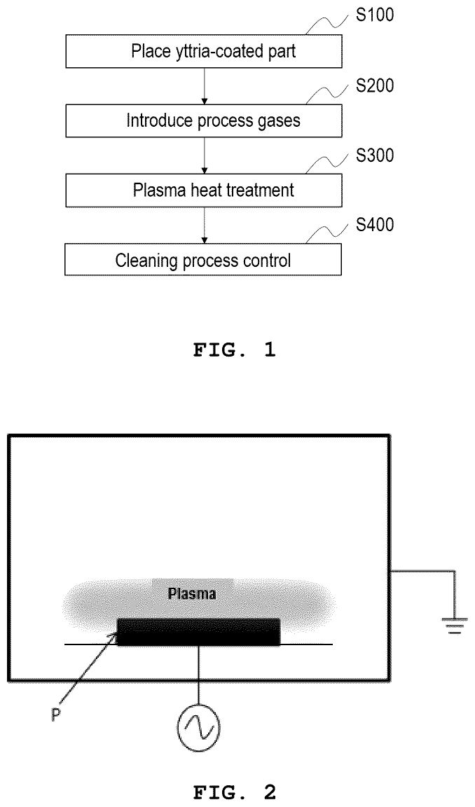

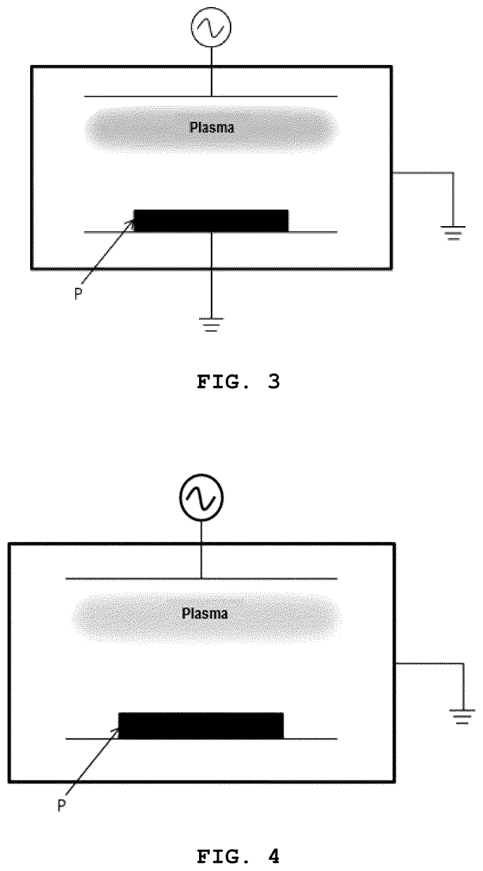

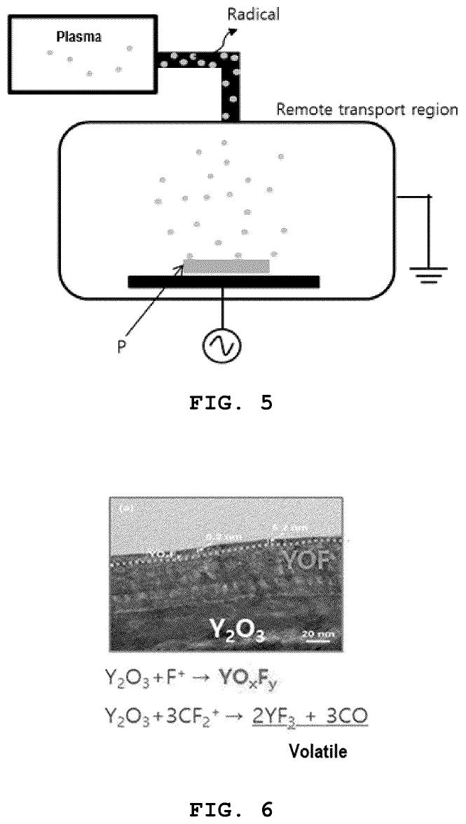

FIG. 1 is a flowchart showing a fluorination cleaning method for forming yttrium oxyfluoride on an yttria-coated part for a semiconductor dry etching system according to the present disclosure, FIG. 2 schematically shows a plasma generation mode of a first embodiment, which is executed in a cleaning process control step included in a fluorination cleaning method for forming yttrium oxyfluoride on an yttria-coated part for a semiconductor dry etching system according to the present disclosure, and FIG. 3 schematically shows a plasma generation mode of a second embodiment, which is executed in a cleaning process control step included in a fluorination cleaning method for forming yttrium oxyfluoride on an yttria-coated part for a semiconductor dry etching system according to the present disclosure. FIG. 4 schematically shows a plasma generation mode of a third embodiment, which is executed in a cleaning process control step included in a fluorination cleaning method for forming yttrium oxyfluoride on an yttria-coated part for a semiconductor dry etching system according to the present disclosure, FIG. 5 schematically shows a plasma generation mode of a fourth embodiment, which is executed in a cleaning process control step included in a fluorination cleaning method for forming yttrium oxyfluoride on an yttria-coated part for a semiconductor dry etching system according to the present disclosure, and FIG. 6 shows the results of observing the coating layer of an yttria-coated part for a semiconductor dry etching system using an electron microscope after performing fluorination cleaning through a fluorination cleaning method for forming yttrium oxyfluoride on an yttria-coated part according to the present disclosure.

The fluorination cleaning method for forming yttria oxyfluoride on an yttria-coated part for a semiconductor dry etching system according to the present disclosure is a method for cleaning a part (component) having a plasma-resistant yttria (Y₂O₃) coating layer for a semiconductor dry etching system. As shown in FIGS. 1 to 6, the method generally includes a part placement step (S100), a process gas introduction step (S200), a plasma heat treatment step (S300), and a cleaning process control step (S400).

Specifically, the fluorination cleaning method for forming yttria oxyfluoride on an yttria-coated part for a semiconductor dry etching system according to the present disclosure is a method for cleaning a part (component) having a plasma-resistant yttria (Y₂O₃) coating layer for a semiconductor dry etching system. As shown in FIGS. 1 to 6, the method includes: a part placement step (S100) of placing the yttria-coated part in a process chamber of a fluorination cleaning apparatus; a process gas introduction step (S200) of introducing process gases, including the discharge gas Ar, the non-fluorine reactive gas O₂, and CF₄ reactive gas, into a treatment space of the process chamber in which the part is placed in the part placement step (S100); a plasma heat treatment step (S300) of applying a predetermined plasma generation power to the treatment space of the process chamber to generate plasma in the treatment space while creating a thermal environment with a predetermined temperature in the treatment space; and a cleaning process control step (S400) of controlling a combination of a plurality of process parameters among process parameters, including the amounts of gases introduced in the process gas introduction step (S200), the power for generating plasma in the plasma heat treatment step (S300), the treatment time, the heat treatment temperature, the treatment space pressure, the distance between the plasma and the part (the distance between the plasma generation unit and the part), and the number of treatment cycles, by a control module unit so that yttrium oxyfluoride (YOF) is formed on the coating layer of the part.

The part placement step (S100) is, for example, a process of placing an yttria-coated part to be exposed to plasma in a treatment chamber having a plasma reaction space (treatment space), and may be performed by placing an yttria-coated part to be cleaned on the top of a support located in the treatment space and closing the door of the treatment chamber to isolate the treatment space from the outside.

The fluorination cleaning apparatus used in the part placement step (S100) will be described in detail below.

Next, the process gas introduction step (S200) is a process of introducing process gases, including the discharge gas Ar, the non-fluorine reactive gas O₂, and CF₄ reactive gas, into the treatment space at flow rates controlled in the cleaning process control step (S400).

In the process gas introduction step (S200), in addition to Ar gas, an inert gas such as He, Ne, Ar, Kr, or Xe may be used as the discharge gas. Also, in addition to oxygen (O₂) gas, nitrogen (N₂), air, or the like may be used as the non-fluorine reactive gas. Also, in addition to the fluorine-containing reactive gas CF₄, a carbon fluoride gas such as C₂F₆ or C₄F₈, or nitrogen trifluoride (NF₃) gas, etc. may be used. However, in the present disclosure, preferably, argon (Ar) gas is used as the discharge gas, oxygen (O₂) is used as the non-fluorine reactive gas, and carbon tetrafluoride (CF₄) is used as the fluorine-containing reactive gas.

Next, the plasma heat treatment step (S300) is performed by applying a predetermined plasma generation power through a plasma generator to generate plasma in the treatment space while creating a thermal environment with a predetermined temperature in the treatment space using a heating member provided in the treatment space.

The plasma heat treatment step (S300) is performed while the process parameters for plasma generation and heat treatment are controlled by the cleaning process control step (S400) described below.

Next, the cleaning process control step (S400) is performed by controlling a combination of a plurality of process parameters, including the amounts of gases introduced in the process gas introduction step (S200), plasma and heat treatment-related parameters of the plasma heat treatment step (S300), the treatment space pressure, the distance between plasma and the part (distance between the electrode to which plasma RF voltage is applied and the target part), and the number of treatment cycles.

The cleaning process control step (S400) may be performed using various methods which are classified, according to the type of plasma source used in the known plasma etching process, into a reactive ion etching (RIE) method, a plasma etching (PE) method, and a remote plasma source (RPS) method, and may be performed using a floating plasma source method for forming a floating potential.

Specifically, in a first embodiment, the cleaning process control step (S400) is performed by controlling plasma generation power, heat treatment temperature (i.e., part temperature), treatment space pressure, process gas flow rates, and treatment time as the process parameters.

Preferably, the cleaning process control step (S400) of the first embodiment is performed in RIE mode as shown in FIG. 2, and the process parameters to be controlled are a plasma generation power (RF/LF plasma power) of 100 W to 1200 W (preferably 100 W to 300 W), a heat treatment temperature (i.e., part temperature) of room temperature to 600° C. (preferably 250° C. to 300° C.), a treatment pressure of 90 mTorr to 110 mTorr (preferably 100 mTorr), a flow rate ratio between non-fluorine reactive gas and fluorine-containing reactive gas CF₄ of 0:100, and a treatment time of 15 to 180 minutes.

The cleaning mode of the first embodiment is a mode having high reactivity and capable of controlling the heat treatment temperature, and performs cleaning to form yttrium oxyfluoride (YOF) on the coating layer of the part.

In a second embodiment, the cleaning process control step (S400) is performed by controlling LF plasma generation power, heat treatment temperature (i.e., part temperature), treatment space pressure, process gas flow rates, and treatment time as the process parameters.

Preferably, the cleaning process control step (S400) of the second embodiment is performed in PE mode as shown in FIG. 3, and the process parameters to be controlled are an LF plasma generation power of 300 W to 1200 W, a heat treatment temperature (i.e., part temperature) of room temperature to 600° C. (preferably 250° C. to 300° C.), a treatment pressure of 90 mTorr to 550 mTorr (preferably 100 mTorr to 500 mTorr), a flow rate ratio between discharge gas (Ar), non-fluorine reaction gas (O₂) and fluorine-containing reaction gas (CF₄) of 0:(10 to 90):(10 to 90) or 50:(10 to 50):(18 to 45), and a treatment time of 15 to 60 minutes.

The cleaning process control mode of this second embodiment may secure large-area uniformity in the formation of yttrium oxyfluoride (YOF) depending on the arrangement of the plasma generating electrode.

In a third embodiment, the cleaning process control step (S400) may include LF plasma generation power, the ratio between non-fluorine reactive gas (O₂) and fluorine-containing reactive gas (CF₄), and treatment time as the process parameters, and may further include the distance between the plasma and the part (the distance between the plasma generating electrode and the target part) and/or the number of treatment cycles (reaction time).

Preferably, the cleaning process control step (S400) of the third embodiment is performed in floating mode as shown in FIG. 4, and the process parameters to be controlled may be an LF plasma generation power of 1 kW to 7 kW, a ratio between non-fluorine reactive gas (O₂) and fluorine-containing reaction gas (CF₄) of 90:10 or 0:100, and treatment time of 10 to 70 minutes (preferably, 10 to 60 minutes). In the case where the distance between the plasma and the part and/or the number of treatment cycles are further included, the distance between the plasma and the part is preferably 30 mm to 140 mm (preferably 40 mm), and the treatment time is preferably 15 to 60 minutes.

The cleaning process control mode of the third embodiment may reduce or prevent an arcing phenomenon that occurs when an overcurrent flows to one portion for some reason and the voltage further increases, and may secure large-area uniformity in the formation of yttrium oxyfluoride (YOF) depending on the arrangement of the plasma generating electrode.

The third embodiment described above uses a floating plasma source method of forming a floating potential. When the part is placed in plasma, the surrounding electrons and ions collide with the sample, and since the electron speed per unit time is faster than the ion speed, the part has a minus (−) potential, and at some point, the number of electrons entering and the number of positive ions entering reach equilibrium, and the current becomes 0. The potential at this time is called the floating potential.

In a fourth embodiment, as shown in FIG. 5, the cleaning process control step (S400) includes microwave power for remote plasma generation, bias plasma power, the flow rate ratio between non-fluorine reactive gas (O₂) and fluorine-containing reactive gas (CF₄), and treatment time as the process parameters. Preferably, the cleaning process control step (S400) of the fourth embodiment is performed in plasma mode as shown in FIG. 5, and the process parameters to be controlled are preferably a microwave power for remote plasma generation of 1 kW to 2 kW, a bias plasma power of 500 W to 1,000 W (2 MHz plasma), a flow rate ratio between non-fluorine reactive gas (O₂) and fluorine-containing reactive gas (CF₄) of 10:1, and a treatment time of 15 minutes.

The cleaning process control mode of the fourth embodiment is a method of performing cleaning in such a way that the interaction between plasma and parts occurs at a location remove from the plasma, and the cleaning process control method of the fourth embodiment may form yttrium oxyfluoride (YOF) by a surface reaction without direct influence of the plasma.

A fluorination cleaning apparatus for forming yttrium oxyfluoride on an yttria-coated part for performing the above-described fluorination cleaning method for forming yttrium oxyfluoride on an yttria-coated part for a semiconductor dry etching system according to the present disclosure will now be described with reference to the accompanying drawings.

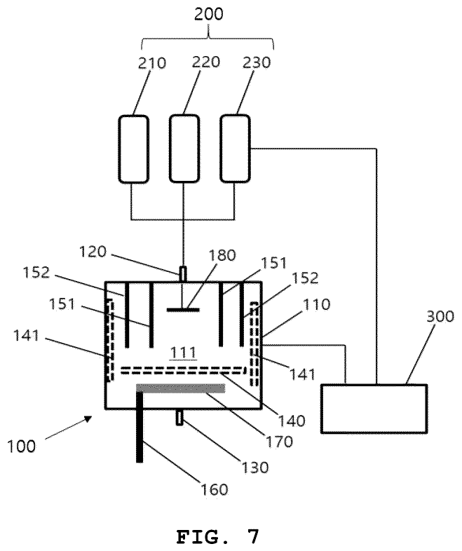

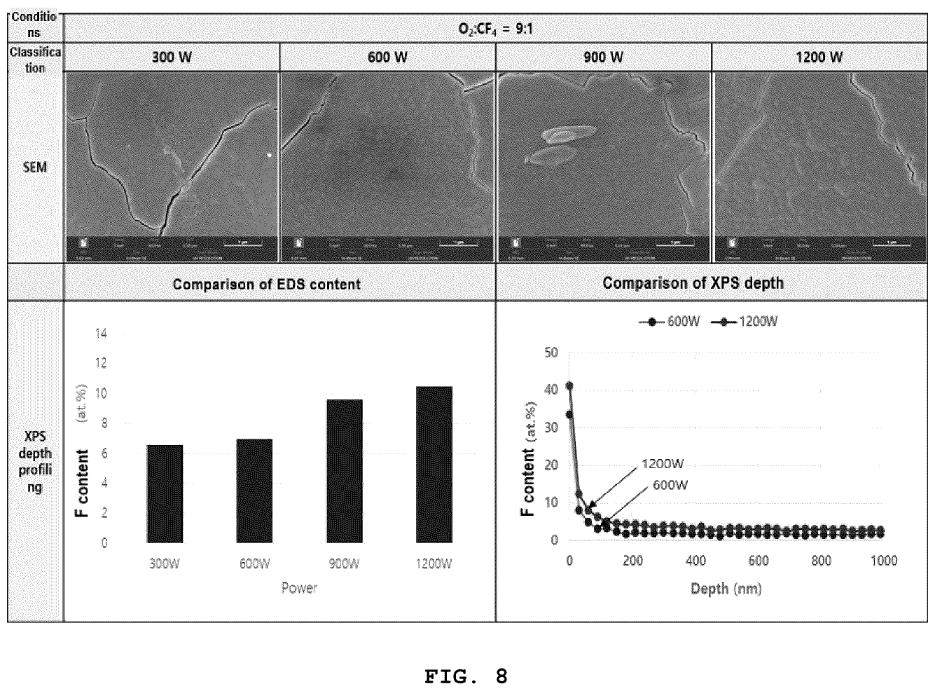

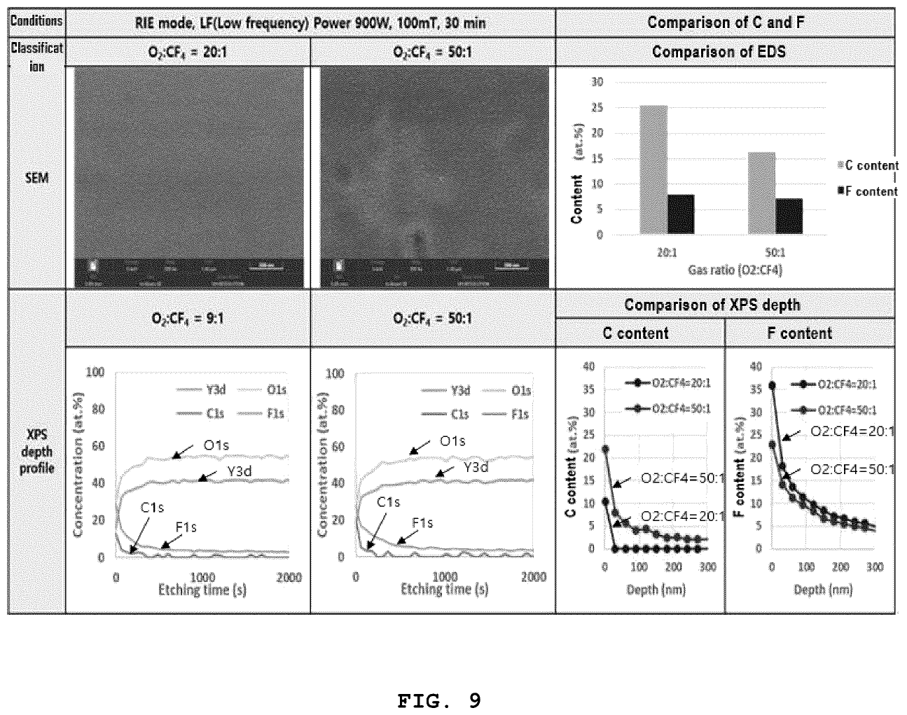

FIG. 7 is a block diagram schematically showing the configuration of a fluorination cleaning apparatus for forming yttrium oxyfluoride on an yttria-coated part for a semiconductor dry etching system according to the present disclosure.

The fluorination cleaning apparatus for forming yttria oxyfluoride on a yttria-coated part for a semiconductor dry etching system according to the present disclosure is a fluorination cleaning apparatus for cleaning a part (component) having a plasma-resistant yttria (Y₂O₃) coating layer for a semiconductor dry etching system, and as shown in FIG. 7, it generally includes a plasma-heat treatment unit 100, a process gas supply device unit 210, 220 and 230, and a control module unit 300.

Specifically, the fluorination cleaning apparatus for forming yttria oxyfluoride on a yttria-coated part for a semiconductor dry etching system according to the present disclosure is a fluorination cleaning apparatus for cleaning a part (component) having a plasma-resistant yttria (Y₂O₃) coating layer for a semiconductor dry etching system, and as shown in FIG. 7, it includes: a plasma-heat treatment unit configured to perform plasma heat treatment on a part (P) having a plasma-resistant yttria (Y₂O₃) coating layer; a process gas supply unit 210, 220 and 230 configured to supply a discharge gas, a non-fluorine reactive gas, and a reactive gas, which are process gases, to the plasma-heat treatment unit; and a control module unit 300 configured to control the plasma heat treatment environment of the plasma-heat treatment unit and the introduction of the process gases supplied from the process gas supply unit 210, 220 and 230.

The plasma-heat treatment unit is configured to perform plasma heat treatment on a part (P) having a plasma-resistant yttria (Y₂O₃) coating layer, and includes: a process chamber body 110 having a treatment space 111 therein; a process gas inlet 120 provided on one side (upper side in the figure) of the process chamber body 110 and configured to introduce process gases into the treatment space 111; a process gas outlet 130 provided on the other side (lower side in the figure) of the process chamber body 110 and configured to discharge the process gases; a heating member 140 and 141 provided inside the process chamber body 110; a plasma generating electrode provided in the process chamber body 110; and a support plate 170 which is provided inside the process chamber body 110 and on which the part (P) is loaded.

The process chamber body 110 is formed in a cylindrical shape, has, on one side thereof, an opening/closing portion (not shown) that opens/closes to load the part, and is configured so that the inside thereof is kept airtight when closed by the opening/closing portion.

In addition, in another embodiment, the process chamber body 110 is configured such that the lower portion forming the bottom is separated from the upper portion. The lower portion is configured to be able to move up and down by an up-and-down driving device (not shown), so that the part is loaded in a state in which the lower portion is moved down, and then the lower portion is moved up to close the treatment space of the process chamber body 110.

The process gas inlet 120 may be provided at the central portion of the upper side of the process chamber body 110, and the process gas outlet 130 may be provided at the central portion of the lower side of the process chamber body 110.

The heating member is configured to heat a plate-shaped part such as a showerhead, and/or a cylindrical part such as a liner.

In one embodiment, the heating member is composed of a plurality of ring-shaped heaters 140 arranged at a distance from each other in a radial direction concentrically around the center of the process chamber body 110, and may be configured to be mounted on a cross-shaped mounting means (not shown) within the process chamber body 110.

The heating member may be composed of a spiral heater, a coil heater, or a plate-shaped heater 140.

In another embodiment, the heating member is composed of a ceramic heater 141 provided along the inner wall of the process chamber body 110.

The heating member 141 may be configured such that U-shaped heaters are provided in a zigzag pattern along the inner wall of the process chamber body 110. The heating member 141 may be composed of a spiral ceramic heater, a coil ceramic heater, or a plate-shaped ceramic heater.

The fluorination cleaning equipment may be configured to include the heating member of each of the one embodiment and the other embodiment, or to include the heating members of both the one embodiment and the other embodiments.

The plasma generating electrode is configured to include a ground electrode and a non-grounded electrode to which plasma voltage is applied. In one embodiment, the non-grounded electrode may be composed of a plate-shaped electrode on which an yttria coating part (P) is placed. That is, the support plate 170 may be composed of a non-grounded electrode.

In addition, since the process gas outlet 130 is formed in the central portion of the lower side, a non-grounded electrode connection portion 160 is connected to one side edge of the support plate 170, and accordingly, the other side of the plate-shaped electrode is supported and fixed by a support (not shown).

In addition, the non-grounded electrode is composed of electrodes in the process chamber body 110 at intervals in a radial direction, and a cylindrical yttria-coated part, such as a liner, is positioned between the intervals.

Specifically, the non-grounded electrode includes a first power electrode 151 provided in the process chamber body 110 concentrically around the center of the process chamber body 110 (i.e., provided relatively close to the center), and a second power electrode 152 provided outside the first power electrode 151 at a distance therefrom.

The first power electrode 151 and the second power electrode 152 are arranged in a circular shape when viewed from the top, and for example, a U-shaped electrode member may be provided in a continuous cylindrical shape.

In this case, the support plate 170 is configured to include a base plate and a ceramic plate provided on the upper surface of the base plate, and the lower end of the cylindrical part (P) is placed on the upper surface.

In addition, the support plate 170 may be configured to be rotatably driven by a rotational driving device (not shown) at the bottom of the process chamber body 110.

The plasma-heat treatment unit may further include, at the process gas inlet 120 side in the treatment space 111 of the process chamber body, a diffusion member 180 that allows the process gases introduced through the process gas inlet 120 to diffuse.

The diffusion member 180 may be composed of a diffusion plate provided at a certain distance from the injection end of the process gas inlet 120, wherein the diffusion plate may be formed in a plate shape as shown in the figure, and may be composed of a dome-shaped plate or a triangular plate.

The process gas supply unit 210, 220 and 230 is configured to supply discharge gas, non-fluorine reactive gas, and reactive gas to the plasma-heat treatment unit 100.

The process gas supply unit 210, 220 and 230 is configured to introduce the discharge gas Ar, the non-fluorine reactive gas O₂, and CF₄ reactive gas, which are process gases, into the treatment space 111 at flow rates controlled by the control unit 300.

In addition to Ar gas, inert gas such as He, Ne, Ar, Kr, or Xe may be used as the discharge gas. Also, in addition to oxygen (O₂) gas, nitrogen (N₂), air, etc. may be used as the non-fluorine reactive gas. Also, in addition to the fluorine-containing reactive gas CF₄, a carbon fluoride gas such as C₂F₆ or C₄F₈, or nitrogen trifluoride (NF₃) gas, etc. may be used. However, in the present disclosure, preferably, argon (Ar) gas is used as the discharge gas, oxygen (O₂) is used as the non-fluorine reactive gas, and carbon tetrafluoride (CF₄) is used as the fluorine-containing reactive gas.

The control module unit 300 is a unit configured to control the plasma heat treatment environment of the plasma-heat treatment unit 100 and the introduction of process gases supplied from the process gas supply unit 210, 220 and 230, and controls a combination of a plurality of process parameters, including the process gas introduction amounts, plasma generation power, treatment time, heat treatment temperature, treatment space pressure, and the number of treatment cycles described above to perform cleaning while forming a yttrium oxyfluoride (YOF) layer of a predetermined thickness on the yttria-coated part.

Meanwhile, the inventor of the present disclosure conducted experiments to confirm the process parameter control included in the fluorination cleaning method for forming yttrium oxyfluoride on an yttria-coated part for a semiconductor dry etching system according to the present disclosure. The experimental results will now be described.

First, the experimental results obtained through the fluorination cleaning method using the process parameters of the first embodiment will be described with reference to FIGS. 8 to 11.

FIG. 8 is a table showing the results of comparing the surface microstructure depending on power and the F contents depending on power and depth. As shown therein, it was confirmed that, as the power increased, the F content increased. FIG. 9 is a table showing the results of comparing the surface microstructure depending on the O₂ flow rate at a fixed power in RIE mode and the C and F contents depending on the O₂ flow rate and depth. As shown therein, as a result of EDS and XPS depth profiling, it was confirmed that, as the oxygen flow rate increased, the C content decreased, the F content increased, and there was an appropriate O₂ flow rate for removing carbon, and that, as the O₂ flow rate increased and the CF₄ flow rate decreased, fluorination decreased.

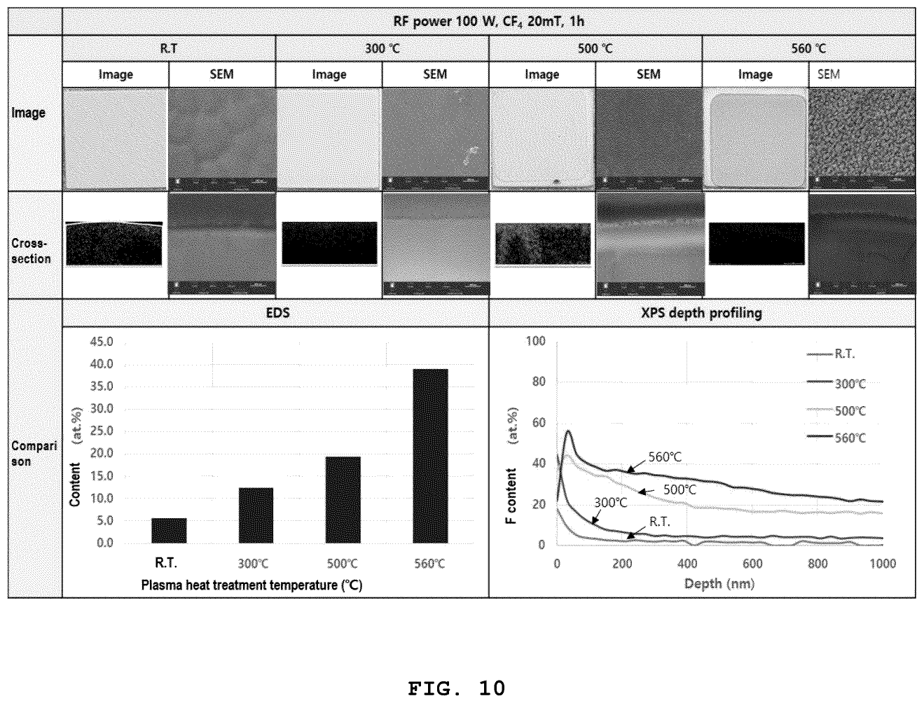

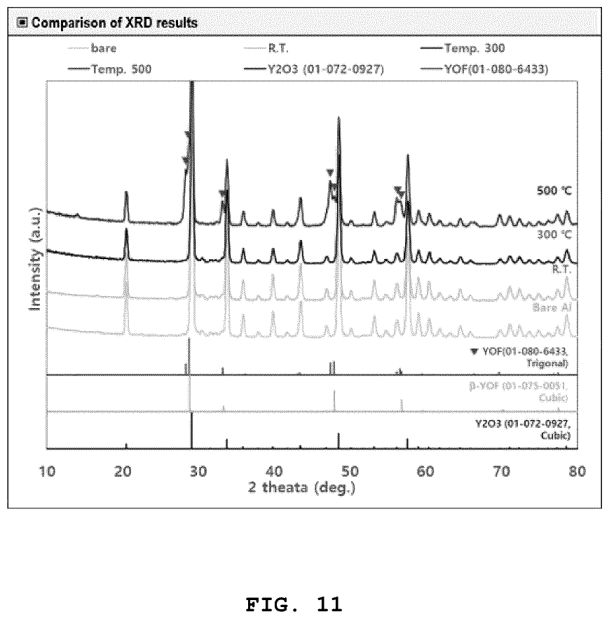

FIG. 10 is a table showing the results of comparing the surface/cross-section microstructure depending on the reaction temperature and the F content according to the reaction temperature and depth. As shown therein, it was confirmed that, as the reaction temperature increased, the F content increased, the fluorinated layer thickness F content increased, and the microstructure particle size increased. FIG. 11 is a table showing the results of XRD analysis depending on the reaction temperature, and shows the change in Y₂O₃ crystal structure depending on the reaction temperature. As shown therein, it was confirmed that there was no difference in the Y₂O₃ crystal structure after fluorination at room temperature (R.T) to 300° C., and the peak of the YOF crystal was observed after fluorination at 500° C. In the specimen after fluorination at 500° C., a YOF layer of about 500 nm was observed.

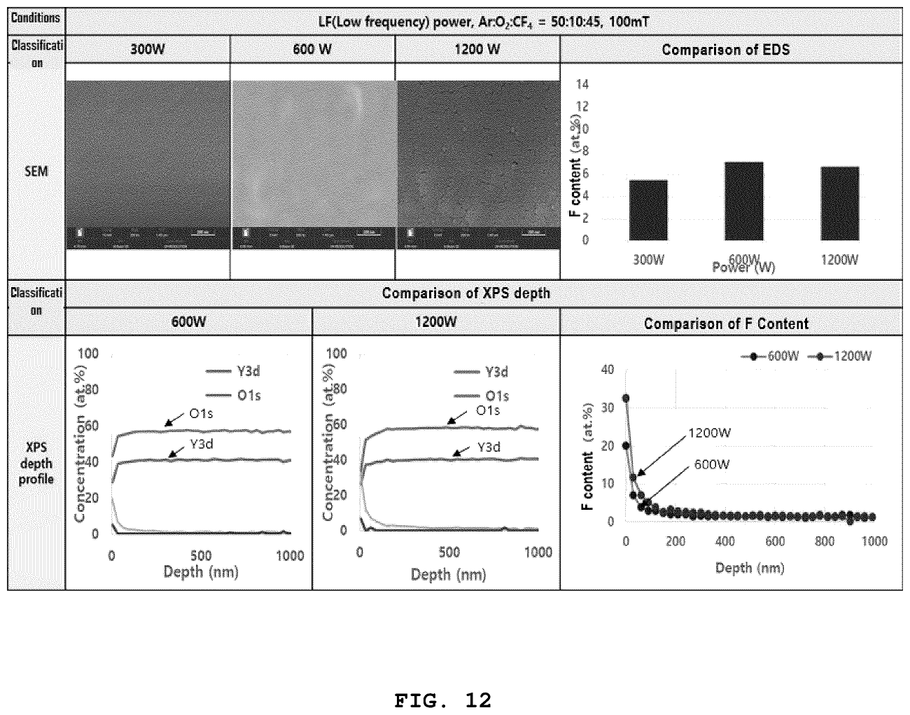

The experimental results obtained through the fluorination cleaning method using the process parameters of the second embodiment will now be described with reference to FIGS. 12 to 15.

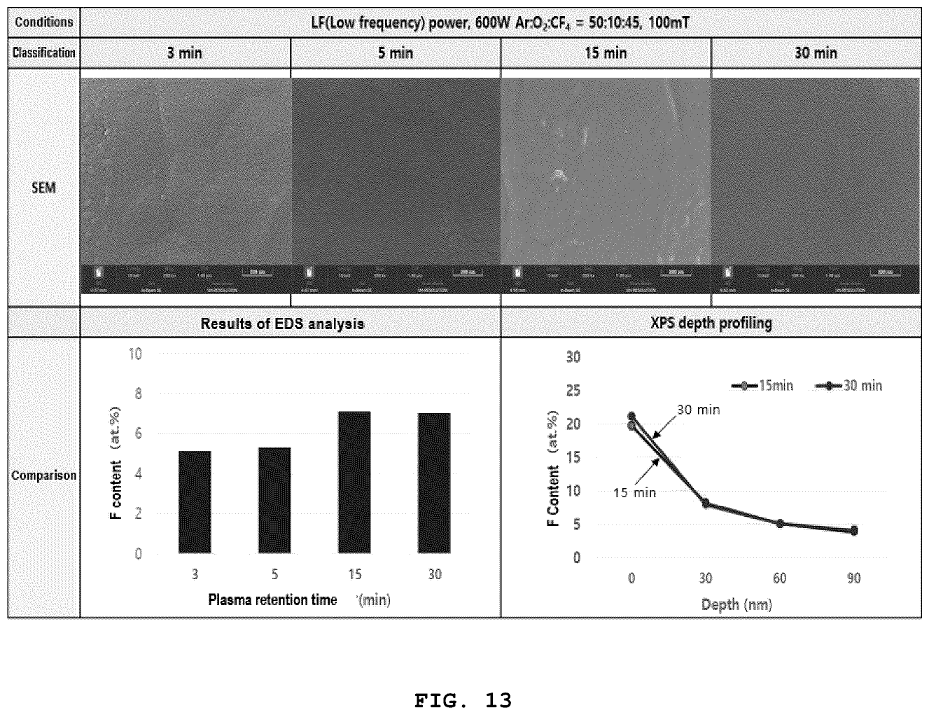

FIGS. 12 and 13 are tables showing the results of comparing the surface microstructure depending on power and reaction time in PE mode, and the F content and C content according to reaction time and depth. As shown therein, as a result of EDS analysis, it was confirmed that there was no change in the F content at a power of 600 W or higher. However, in the results of XPS analysis, it was confirmed that the F content on the surface slightly increased as the power increased.

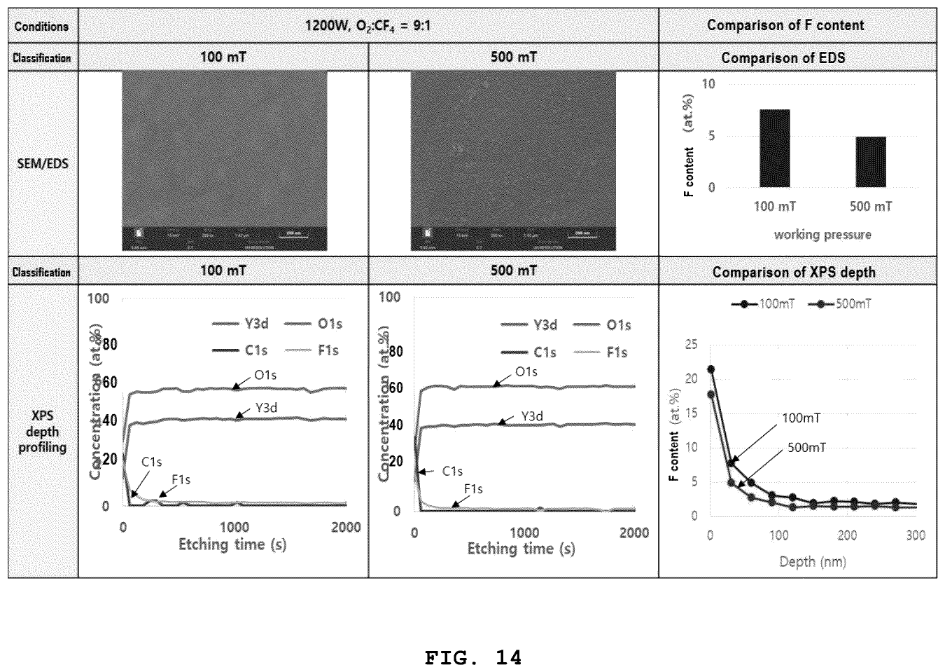

FIG. 14 is a table showing the results of comparing the surface microstructure depending on the chamber working pressure (treatment pressure) and the F content depending on the working pressure and depth. As shown therein, as a result of EDS and XPS depth profiling, it was confirmed that the F content decreased as the chamber working pressure increased. This is believed to be because the scattering of ions increased as the chamber working pressure increased, resulting in a decrease in fluorination.

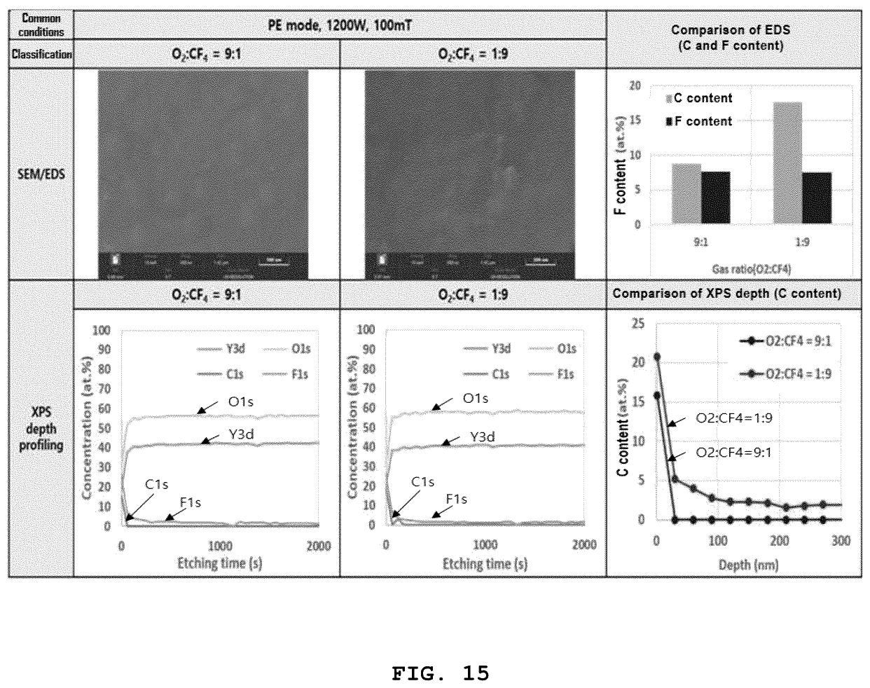

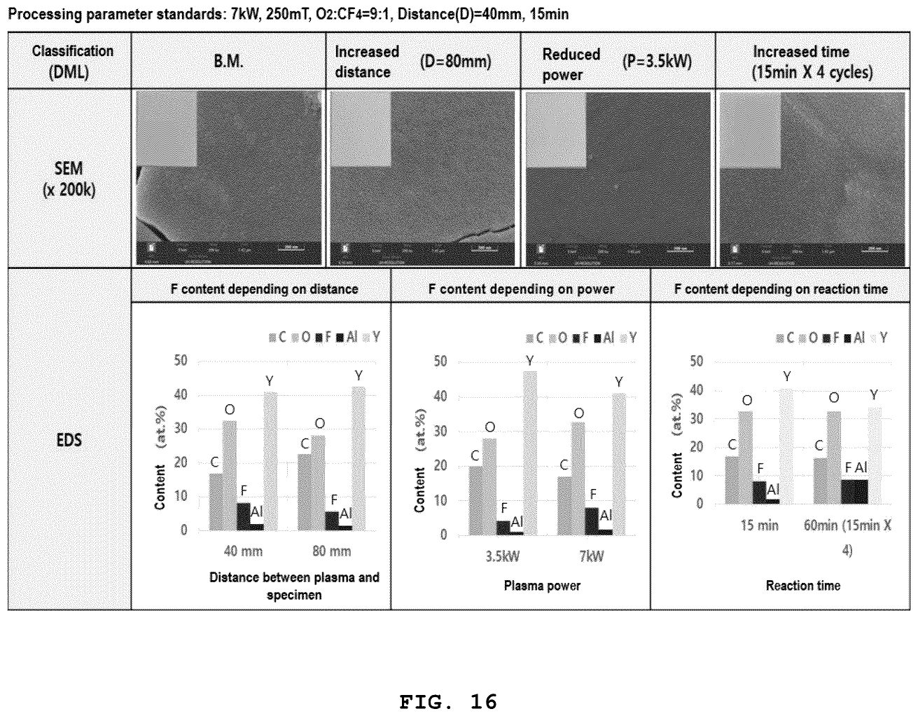

FIG. 15 is a table showing the results of comparing the surface microstructure depending on the gas flow ratio between O₂ and CF₄, and the F content and C content depending in the gas flow ratio between O₂ and CF₄ and depth. As shown therein, as a result of EDS and XPS depth profiling, it was confirmed that, the O₂ flow rate increased, the C content decreased, but the F content did not change.

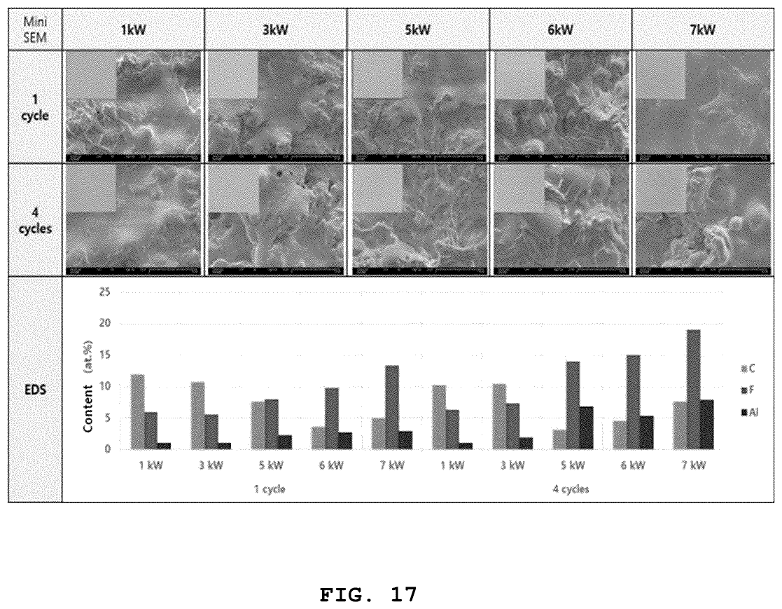

The experimental results obtained through the fluorination cleaning method using the process parameters of the third embodiment will now be described with reference to FIGS. 16 and 17.

FIG. 16 is a table showing the results of EDS analysis under the following process parameters: the distance (D) from plasma generating electrode: 40 mm; power: 7 kW; 250 mT; O₂: CF₄=9:1; and the reaction time: 15 min. FIG. 17 is a table showing the results of evaluating fluorination cleaning depending on the plasma power and the reaction time. As shown therein, it was confirmed that, when the distance between the plasma generating electrode and the specimen increased beyond the upper limits of the process parameters, the F content decreased, and as the plasma power increased, the F content increased. In addition, it was confirmed that, when the reaction time exceeded 60 min, the F content slightly increased, but an F content exceeding a certain concentration was meaningless because there was concern about particle generation during the etching process. In other words, it was confirmed that, when the reaction time exceeded 60 min, there was concern that etching would actually occur and the F content would decrease.

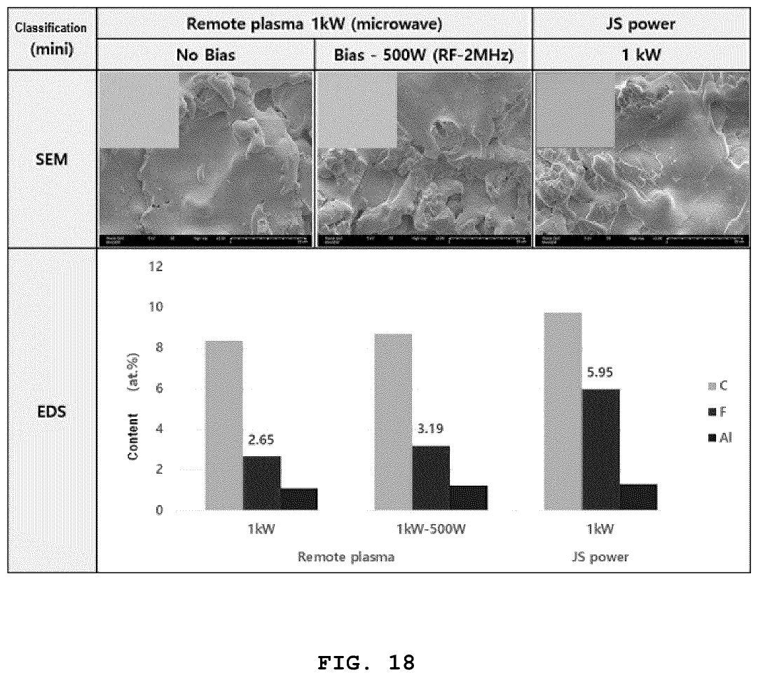

The experimental results obtained through the fluorination cleaning method using the process parameters of the fourth embodiment will now be described with reference to FIG. 18.

FIG. 18 is a table showing the results of performing fluorination cleaning on Y₂O₃ using the process parameters of the fourth embodiment. As shown therein, it was confirmed that the F content was in the order of remote plasma<remote plasma-bias<LF plasma, indicating that LF plasma was most suitable for surface reaction.

According to the method and the apparatus for forming yttrium oxyfluoride on an yttria-coated part for a semiconductor dry etching system according to the present disclosure as described above, it is possible to shorten the time of aging for ensuring a normal etching rate in a seasoning process for the semiconductor dry etching system including the yttria (Y₂O₃)-coated part, thereby improving productivity. In addition, since the composition of YOF may be controlled, the compatibility of the system is excellent.

In addition, according to the present disclosure, it is possible to increase the coating life of the coating life of a part coated with a plasma-resistant coating material, thereby increasing economic efficiency. In addition, it is possible to impart high density and high strength to an yttria (Y₂O₃)-coated part for a semiconductor dry etching system, and maximally reduce the generation of contaminant particles to ensure a normal etching rate.

The embodiments described herein and the accompanying drawings are merely illustrative of some of the technical ideas included in the present disclosure. Therefore, the embodiments disclosed herein are not intended to limit the technical idea of the present disclosure but rather to explain the same, and thus it is obvious that the scope of the technical idea of the present disclosure is not limited by these embodiments. All modifications and specific embodiments that may be easily inferred by those skilled in the art within the scope of the technical idea included in the specification and drawings of the present disclosure should be interpreted as being included in the scope of the present disclosure.

What is claimed is:

1. A fluorination cleaning method for forming yttrium oxyfluoride on an yttria (Y₂O₃)-coated part for a semiconductor dry etching system, comprising:
a part placement step of placing the yttria-coated part in a process chamber;
a process gas introduction step of introducing a discharge gas, a non-fluorine reactive gas, and a reactive gas, which are process gases for fluorination cleaning, into the process chamber;
a plasma heat treatment step of applying heat and plasma to the process chamber; and
a cleaning process control step of controlling process parameters of the process gas introduction step and the plasma heat treatment step so that a fluoride layer is formed on an yttria coating layer of the yttria-coated part.

2. The method according to claim 1, wherein the cleaning process control step comprises controlling a combination of a plurality of process parameters among process parameters, including process gas introduction amounts, plasma generation power, treatment time, heat treatment temperature, treatment space pressure, a distance between plasma and the part, and the number of treatment cycles.

3. The method according to claim 1, wherein the cleaning process control step comprises controlling the process parameters so that an yttrium oxyfluoride layer is formed on the yttria-coating layer of the yttria-coated part.

4. The method according to claim 2, wherein the cleaning process control step comprises controlling the process parameters so that an yttrium oxyfluoride layer is formed on the yttria-coating layer of the yttria-coated part.

5. The method according to claim 1, wherein the cleaning process control step comprises controlling plasma generation power, heat treatment temperature, treatment space pressure, process gas flow rates, and treatment time as the process parameters.

6. The method according to claim 2, wherein the cleaning process control step comprises controlling plasma generation power, heat treatment temperature, treatment space pressure, process gas flow rates, and treatment time as the process parameters.

7. The method according to claim 3, wherein the cleaning process control step comprises controlling plasma generation power, heat treatment temperature, treatment space pressure, process gas flow rates, and treatment time as the process parameters.

8. The method according to claim 5, wherein the cleaning process control step comprises controlling the plasma generation power (RF power) to 100 W to 1200 W, the heat treatment temperature to room temperature to 600° C., the treatment space pressure to 90 mTorr to 110 mTorr, the flow rate ratio between non-fluorine reactive gas and fluorine-containing reactive gas CF₄ to 0:100, and the treatment time to 15 to 180 minutes.

9. The method according to claim 1, wherein the cleaning process control step comprises controlling LF plasma generation power, heat treatment temperature, treatment space pressure, process gas flow rates, and treatment time as the process parameters.

10. The method according to claim 2, wherein the cleaning process control step comprises controlling LF plasma generation power, heat treatment temperature, treatment space pressure, process gas flow rates, and treatment time as the process parameters.

11. The method according to claim 3, wherein the cleaning process control step comprises controlling LF plasma generation power, heat treatment temperature, treatment space pressure, process gas flow rates, and treatment time as the process parameters.

12. The method according to claim 9, wherein the cleaning process control step comprises controlling the LF plasma generation power to 300 W to 1,200 W, the heat treatment temperature to room temperature to 600° C., the treatment space pressure to 90 mTorr to 550 mTorr, the flow rate ratio between discharge gas (Ar), non-fluorine reactive gas (O₂), and fluorine-containing reactive gas (CF₄) to 0:(10 to 90):(10 to 90), or 50:(10 to 50):(18 to 45), and the treatment time to 15 to 60 minutes.

13. The method according to claim 1, wherein the cleaning process control step comprises controlling plasma generation power, the flow rate ratio between non-fluorine reactive gas (O₂) and fluorine-containing reactive gas (CF₄), and treatment time as the process parameters, and further comprises controlling at least one of the distance between plasma and the part, and the number of treatment cycles.

14. The method according to claim 2, wherein the cleaning process control step comprises controlling plasma generation power, the flow rate ratio between non-fluorine reactive gas (O₂) and fluorine-containing reactive gas (CF₄), and treatment time as the process parameters, and further comprises controlling at least one of the distance between plasma and the part, and the number of treatment cycles.

15. The method according to claim 3, wherein the cleaning process control step comprises controlling plasma generation power, the flow rate ratio between non-fluorine reactive gas (O₂) and fluorine-containing reactive gas (CF₄), and treatment time as the process parameters, and further comprises controlling at least one of the distance between plasma and the part, and the number of treatment cycles.

16. The method according to claim 13, wherein the cleaning process step control comprises controlling the LF plasma generation power to 1 kW to 7 kw, the flow rate ratio between non-fluorine reactive gas (O₂) and fluorine-containing reaction gas (CF₄) to 90:10 or 0:100, the treatment time to 15 to 60 minutes, and the distance between plasma and the part to 30 to 50 mm.

17. The method according to claim 1, wherein the cleaning process control step comprises controlling microwave power for remote plasma generation, bias plasma power, the flow rate ratio between non-fluorine reactive gas (O₂) and fluorine-containing reactive gas (CF₄), and treatment time as the process parameters.

18. The method according to claim 2, wherein the cleaning process control step comprises controlling microwave power for remote plasma generation, bias plasma power, the flow rate ratio between non-fluorine reactive gas (O₂) and fluorine-containing reactive gas (CF₄), and treatment time as the process parameters.

19. The method according to claim 3, wherein the cleaning process control step comprises controlling microwave power for remote plasma generation, bias plasma power, the flow rate ratio between non-fluorine reactive gas (O₂) and fluorine-containing reactive gas (CF₄), and treatment time as the process parameters.

20. The method according to claim 17, wherein the cleaning process control step comprises controlling the microwave power for remote plasma generation to 1 kW to 2 kW, the bias plasma power to 500 W to 1,000 W (2 MHz plasma), the flow rate ratio between non-fluorine reactive gas (O₂) and fluorine-containing reactive gas (CF₄) to 10:1, and the treatment time to 15 minutes.
